(19) United States
(12) Patent Application Publication
(10) Pub. No.: US 2024/0420501 A1
(43) Pub. Date: Dec. 19, 2024

(54) AN OPTICAL FINGERPRINT SENSOR AND A METHOD FOR DETECTING A FINGERPRINT

(71) Applicant: FINGERPRINT CARDS ANACATUM IP AB, GÖTEBORG (SE)

(72) Inventors: Ju-Chin CHEN, Taipei City (TW); Chin Jung KUO, Zhubei City (TW)

(73) Assignee: FINGERPRINT CARDS ANACATUM IP AB, GÖTEBORG (SE)

(21) Appl. No.: 18/720,749

(22) PCT Filed: Dec. 16, 2022
(86) PCT No.: PCT/SE2022/051198

§ 371 Date: Jun. 17, 2024

(30) Foreign Application Priority Data
Dec. 20, 2021 (SE) 2151561-4

(51) Int. Cl. G06V 40/13; G06V 10/141; G06V 10/143; G06V 10/147

(52) U.S. Cl. CPC G06V 40/1318; G06V 10/141; G06V 10/143; G06V 10/147

(57) ABSTRACT

An optical fingerprint sensor configured to be arranged under an at least partially transparent display panel comprises an array of color controllable light sources. The optical fingerprint sensor comprises an image sensor comprising a photodetector pixel array; an array of microlenses arranged under the color controllable light sources; a color filter layer arranged under the array of microlenses comprising alternating filter element types of different colors for adjacent subsets of pixels in the photodetector pixel array. The color controllable light sources are controllable, in response to a first finger condition, to emit light of uniform color being a mix of the colors of the filter elements, and in response to a second finger condition, to emit a color pattern including the colors of the filter elements, wherein groups of color controllable light sources are controlled to emit light corresponding to a color of the filter elements.

### FIELD OF THE INVENTION

The present invention relates to optical fingerprint sensor configured to be arranged under an at least partially transparent display panel. The invention further relates to an electronic device, to a method, and to a control unit for executing the method.

### BACKGROUND OF THE INVENTION

Biometric systems are widely used as means for increasing the convenience and security of personal electronic devices, such as mobile phones etc. Fingerprint sensing systems, in particular, are now included in a large proportion of all newly released consumer electronic devices, such as mobile phones.

Optical fingerprint sensors have been known for some time and may be a feasible alternative to e.g., capacitive fingerprint sensors in certain applications, for example in under-display applications. Optical fingerprint sensors may for example be based on the pinhole imaging principle and/or may employ micro-channels, i.e., collimators or microlenses to focus incoming light onto an image sensor.

The fingerprint image quality depends at least partly on the humidity of the finger. For example, a wet finger cause more specular reflections than diffuse reflections. In contrast, a dry finger cause more diffuse reflections than specular reflections. The different reflection properties of dry and humid fingers lead to difficulties in maintaining high image quality for both dry and humid fingers.

Accordingly, there is room for improvement with regards to imaging fingerprints of different humidity levels.

### SUMMARY

In view of above-mentioned and other drawbacks of the prior art, it is an object of the present invention to provide an optical fingerprint sensor that at least alleviates some of the drawbacks of prior art.

According to a first aspect of the invention, there is provided an optical fingerprint sensor configured to be arranged under an at least partially transparent display panel and configured to capture an image of an object located on an opposite side of the at least partly transparent display panel which comprises an array of color controllable light sources configured for illuminating the object for capturing an image.

The optical fingerprint sensor comprises an image sensor comprising a photodetector pixel array; an array of microlenses arranged under the color controllable light sources to redirect light towards the photodetector pixel array; a color filter layer arranged under the array of microlenses to at least partly cover the photodetector pixel array, the color filter layer comprising alternating filter element types of different colors for adjacent subsets of pixels in the photodetector pixel array.

The color controllable light sources are controllable, in response to a first finger condition, to emit light of uniform color including a mix of the colors of the filter elements, and in response to a second finger condition, to emit a color pattern including the colors of the filter elements, wherein groups of color controllable light sources are controlled to emit light corresponding to a respective color of the filter elements.

The present invention is based the realization that by changing the illumination of the emitted light from the color controllable light sources between a mixed color and a distinct color pattern it is possible to improve the fingerprint image quality. In particular, the varied illumination makes use of the knowledge of the different reflection properties of dry and humid or normal fingers. The invention is especially useful for providing increased image quality for dry fingers without compromising the image quality for normal humid fingers. For example, a pin hole layer with relatively small hole size is often used to achieve high-resolution fingerprint images. However, a drawback of such a pin hole layer is that little light can pass through and reach the image sensor. This especially affects imaging of fingers where the reflection is dominated by diffuse scattering where light is scattered through a large angle. The embodiments of the present disclosure at least alleviate this situation for fingers where diffuse reflections are dominant.

The light emitted in response to the first finger condition may be within a single wavelength band of light at least partly transmissible through both filter element types.

The light of uniform color may be emitted by controlling each of the color controllable light sources to emit light of the mixed color. Further, that the color is uniform is that the color across the illuminated areas as provided by the array of color controllable light sources is substantially the same, or at least within a relatively narrow wavelength band.

A group of color controllable light sources may comprise at least two light sources or pixels.

Further, a subset of pixels in the photodetector pixel array comprises as least one or more pixels.

Preferably, one pixel in the photodetector pixel array correspond to more than one of the color controllable light sources.

Each of the color filter elements has a spectral transmission band corresponding to a color of light, e.g., a first color and a second color. Thus, the color filter elements are configured to allow the transmission of light in a specific spectral band. The spectral transmission bands of the two filter type elements may be non-overlapping.

The color filter is provided in the form of a color filter layer on the image sensor, either directly or in-directly on the pixels, i.e., there may be e.g., protective layers in between if so needed.

Preferably, the color filter layer cover the photodetector pixel array.

The image sensor may be a thin-film transistor (TFT) based image sensor. Such sensors provide a cost-efficient solution for under display fingerprint imaging sensors. The TFT image sensor may be a back illuminated TFT image sensor or a front illuminated TFT image sensor. The TFT image sensor may be arranged as a Hot-zone, Large Area or Full display solution. Other suitable types of image sensors include CMOS or CCD sensors.

According to embodiments, the transparent display panel may comprise a color controllable light source. Various types of displays can be used in accordance with embodiments. For example, display panels based on OLED, u-LED with any type of tri-stimulus emission like RGB, CMY or others.

In any case, it is important that the color filters applied onto the image sensor pixels are selected to match the spectral bands of the light emitted by the display.

According to embodiments, the spectral transmission band of the color filter elements in each of the color arrays are configured to match a respective color of the emitted light from the color controllable light source.

Microlenses provide an advantageous way to redirect light onto the photodetector pixel array. In particular, each is microlens may be arranged to redirect light onto at least one pixel.

The microlenses may be arranged in an array having a pitch in the range of 10 μm to 50 μm.

The microlenses may be circular lenses having a diameter in the range of 10 μm to 50 μm.

Moreover, the microlens may have a height in the range of 2 μm to 60 μm.

A radius of curvature of the microlenses may be in the range of 10 μm to 25 μm.

With the above-described possible configurations of the plurality of microlenses, an optical fingerprint senor for use under a display panel can be provided, and the specific configuration can be adapted based on the properties of the display panel and on the requirements for the application at hand.

The outer surface of a display panel under which the optical fingerprint sensor is arranged may also be referred to as a sensing surface. The operating principle of the described optical fingerprint sensor is that light emitted by pixels, i.e., color controllable light sources, in the display panel will be reflected by a finger placed on the sensing surface, and the reflected light is received by the microlenses and subsequently redirected onto a corresponding subarray of pixels or a single pixel in the photodetector pixel array. In case of a subarray, an image of a portion of a finger can be captured for each subarray. By combining the images from all of the light redirecting elements, an image representing the fingerprint can be formed and subsequent biometric verification can be performed.

In embodiments, when emitting light in response to the second finger condition, the color pattern comprises portions of light adapted to be transmissible through one of the filter types and not through the other filter type. This advantageously provides for detecting the fingerprint pattern via only a portion of the pixels of the image sensor, e.g., detecting one of either normal incident light on the image sensor or oblique incident light depending on the relative location between the portions of light and the respective color filter element. However, in both cases the contrast in normal humid finger images is improved.

In one preferred embodiment, the color pattern may be a chess board pattern of alternating colors of light.

Further, the alternating filter element types of the color filter layer may be arranged in a chess board pattern.

In one embodiment, in response to the second finger condition, portions of the color controllable light sources may be configured to emit light of the same color as the color of the filter type arranged under the respective portion of the color controllable light sources. This advantageously provides for detecting normal incident light on the image sensor.

In one embodiment, in response to the second finger condition, portions of the color controllable light sources may be configured to emit light of the same color as the color of the filter type adjacent to the filter type arranged under the respective portion of the color controllable light sources. This advantageously provides for detecting oblique incident light on the image sensor.

The first and second finger conditions are related to the humidity or moisture level of the object.

Preferably, the first finger condition may be that the object is determined to have a moisture level below a threshold indicative of a dry finger. Further, the second finger condition may be that the object is determined to have a moisture level above a threshold indicative of a finger having normal humidity.

Determining the finger condition in the form of a humidity may be performed by capacitive measurements perform by for example a touch screen or by other capacitive sensing means. Such humidity determination can be performed by a device not included in the optical fingerprint sensor, whereby processing circuitry receives the result of such determination. In other embodiments, the optical fingerprint sensor comprises the processing circuitry.

Thus, in embodiments, the optical fingerprint sensor may comprise, or may be connected to, processing circuitry for determining whether or not the object is classified to be of the first finger condition related to being a dry finger.

In preferred embodiments, the color controllable light sources may be comprised in an organic light emitting diode (OLED) display.

In one embodiment, the light emitted in response to the first finger condition may cyan light, and the color filter layer may comprise alternating green and blue filter elements.

In embodiments, the color pattern emitted in response to the second finger condition may comprise distinguished green and blue areas.

In embodiments the optical fingerprint sensor may comprise an opaque layer arranged under the color filter layer and covering an upper surface of the photodetector pixel array, wherein the opaque layer further comprises a plurality of separate openings. The openings may be arranged as a collimator.

According to a second aspect of the invention, there is provided an electronic device comprising: an at least partly transparent display panel; the optical fingerprint sensor according to the first aspect, and processing circuitry configured to: receive a signal from the optical fingerprint sensor indicative of a fingerprint of a finger touching the at least partly transparent display panel, perform a fingerprint authentication procedure based on information comprised in the signal.

The display panel may for example be based on OLED, LCD, μLED and similar technologies. Thereby, in-display biometric imaging is enabled.

The electronic device may be e.g., a mobile device such as a mobile phone (e.g. Smart Phone), a tablet, a phablet, etc.

Further effects and features of the second aspect of the invention are largely analogous to those described above in connection with the first aspect of the invention.

According to a third aspect of the invention, there is provided a method for detecting a fingerprint using an optical fingerprint sensor arranged under an at least partially transparent display panel and configured to capture an image of an object located on an opposite side of the at least partly transparent display panel which comprises an array of color controllable light sources, the optical fingerprint sensor comprises: an image sensor comprising a photodetector pixel array; an array of microlenses arranged under the color controllable light sources to redirect light towards the photodetector pixel array; a color filter layer arranged under the array of microlenses to at least partly cover the photodetector pixel array, the color filter layer comprising alternating filter element types of different colors for adjacent subsets of pixels in the photodetector pixel array; wherein the method comprises: detecting, using the optical fingerprint sensor, the object located on the opposite side of the at least partly transparent display panel; determining whether the object is classified according to a first finger condition or to a second finger condition depending on a humidity level of the object; wherein in response to a determining that the object is classified according to the first finger condition, controlling each color controllable light source to emit light being a mix of the colors of the filter elements, otherwise, controlling groups of color controllable light sources to emit light corresponding to a respective color of the filter elements so that a color pattern including the colors of the filter elements is emitted.

In embodiments, the method may comprise in response to a determining that the object is classified according to the first finger condition, controlling the array of color controllable light sources to emit cyan light, otherwise, controlling the array of color controllable light sources to emit light in a color pattern comprising blue and green light.

Further effects and features of the third aspect of the invention are largely analogous to those described above in connection with the first aspect and the second aspect of the invention.

There is further provided a control unit configured to perform the steps the herein disclosed method.

Further features of, and advantages with, the present invention will become apparent when studying the appended claims and the following description. The skilled person realize that different features of the present invention may be combined to create embodiments other than those described in the following, without departing from the scope of the present invention.

### BRIEF DESCRIPTION OF THE DRAWINGS

These and other aspects of the present invention will now be described in more detail, with reference to the appended drawings showing an example embodiment of the invention, wherein:

FIG. 1 schematically illustrates an example of an electronic device according to embodiments of the invention;

FIG. 2 is a schematic box diagram of an electronic device according to embodiments of the invention;

FIG. 3A schematically illustrates an optical fingerprint sensor arranged under a display according to an embodiment of the invention;

FIG. 3B schematically illustrates an optical fingerprint sensor arranged under a display according to an embodiment of the invention:

FIG. 3C schematically illustrates an optical fingerprint sensor arranged under a display according to an embodiment of the invention;

FIG. 3D schematically illustrates an optical fingerprint sensor arranged under a display according to an embodiment of the invention;

FIG. 4A schematically illustrates a check-board filter layer according to an embodiment of the invention;

FIG. 4B schematically illustrates a check-board filter layer and a corresponding display according to an embodiment of the invention;

FIG. 4C schematically illustrates a check-board filter layer and a corresponding display according to an embodiment of the invention; and

FIG. 5 is a flow-chart of method steps according to embodiments of the invention.

### DETAILED DESCRIPTION OF EXAMPLE EMBODIMENTS

In the present detailed description, various embodiments of the optical fingerprint sensor according to the present invention are mainly described with reference to an optical fingerprint sensor arranged under a display panel. However, it should be noted that the described imaging device also may be used in other optical fingerprint imaging applications such as in an optical fingerprint sensor located under a cover glass or the like.

Turning now to the drawings and in particular to FIG. 1, there is schematically illustrated an example of an electronic device configured to apply the concept according to the present disclosure, in the form of a mobile device 101 with an integrated in-display optical fingerprint sensor 100 and a display panel 104 with a touch screen interface 106. The optical fingerprint sensor 100 may, for example, be used for unlocking the mobile device 100 and/or for authorizing transactions carried out using the mobile device 100, etc.

The optical fingerprint sensor 100 is here shown to be smaller than the display panel 104, but still relatively large, e.g., a large area implementation, In another advantageous implementation the optical fingerprint sensor 100 may be the same size as the display panel 104, i.e. a full display solution. Thus, in such case the user may place his/her finger anywhere on the display panel for biometric authentication. The optical fingerprint sensor 100 may in other possible implementations be smaller than the depicted optical fingerprint sensor, such as providing a hot-zone implementation.

Preferably and as is apparent for the skilled person, the mobile device 100 shown in FIG. 1 further comprises a first antenna for WLAN/Wi-Fi communication, a second antenna for telecommunication communication, a microphone, a speaker, and a phone control unit. Further hardware elements are of course possibly comprised with the mobile device.

It should furthermore be noted that the invention may be applicable in relation to any other type of electronic devices comprising transparent display panels, such as a laptop, a tablet computer, etc.

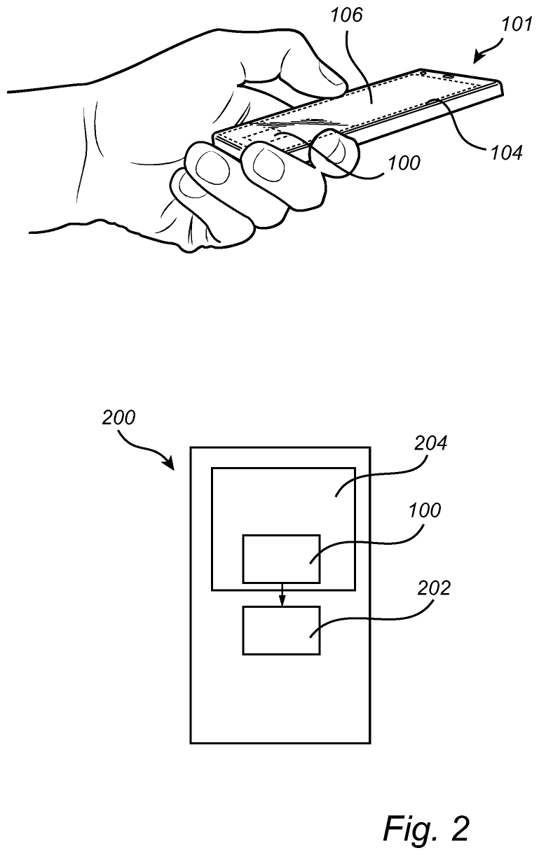

FIG. 2 is a schematic box diagram of an electronic device according to embodiments of the invention. The electronic device 200 comprises a transparent display panel 204 and an optical fingerprint sensor 100 conceptually illustrated to be arranged under the transparent display panel 204 according to embodiments of the invention. Furthermore, the electronic device 200 comprises processing circuitry such as control unit 202. The control unit 202 may be stand-alone control unit of the electronic device 202, e.g., a device controller. Alternatively, the control unit 202 may be comprised in the optical fingerprint sensor 100.

The control unit 202 is configured to receive a signal indicative of a detected object from the optical fingerprint sensor 100. The received signal may comprise image data.

Based on the received signal the control unit 202 is configured to detect a fingerprint and based on the detected fingerprint the control unit 202 is configured to perform a fingerprint authentication procedure. Such fingerprint authentication procedures are considered per se known to the skilled person and will not be described further herein.

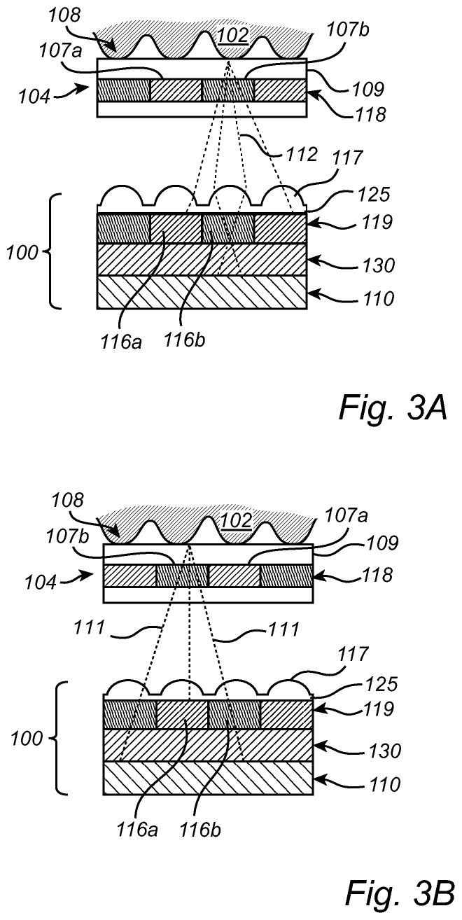

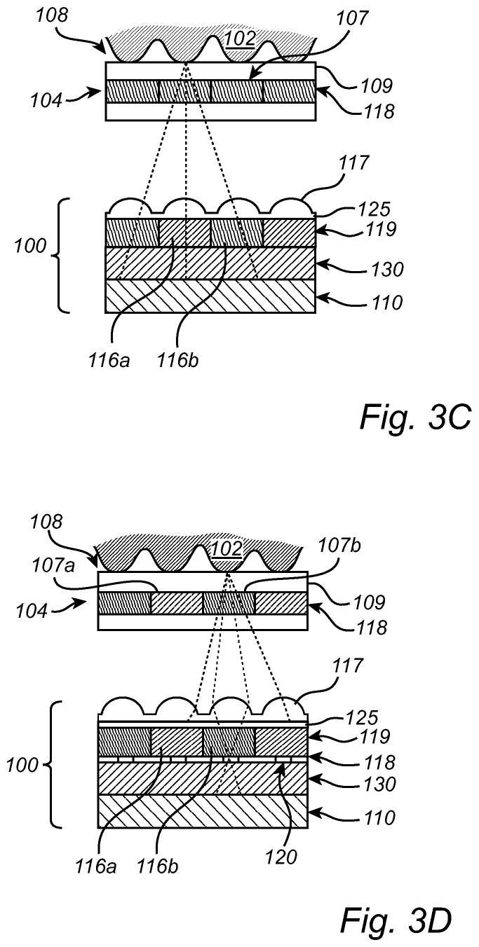

FIGS. 3A-C schematically illustrates an optical fingerprint sensor 100 according to embodiments of the invention. The optical fingerprint sensor 100 is here arranged under an at least partially transparent display panel 104. However, the optical fingerprint sensor 100 may be arranged under any cover structure which is sufficiently transparent, as long as the image sensor receives a sufficient amount of light to capture an image of a biometric object 102 in contact with the outer surface of the cover structure, such as a fingerprint or a palmprint. In the following, an optical fingerprint sensor 100 configured to capture an image of a finger 102 in contact with an outer surface 108 of the display panel 104 is described. The outer surface 108 may be the top surface of a cover glass 109.

The optical fingerprint sensor 100 comprises an image sensor 110 comprising a photodetector pixel array, where each pixel is an individually controllable photodetector configured to detect an amount of incoming light and to generate an electric signal indicative of the light received by the detector. The image sensor 110 may be any suitable type of image sensor, such as a CMOS or CCD sensor connected to associated control circuitry. However, in a preferred embodiment image sensor 108 is a thin-film transistor (TFT) based image sensor which provides a cost-efficient solution. The operation and control of such an image sensor can be assumed to be known and will not be discussed herein.

The optical fingerprint sensor 100 comprises an array of microlenses 117 arranged under a color controllable light source 118 to redirect light towards the photodetector pixel array of the image sensor 110. For acquiring an image of e.g., a fingerprint or palmprint, the color controllable light source 118 may emit light that is reflected by the finger 102 and detected by the pixels of the image sensor 110. There are suitable openings or optical paths past the color controllable light source 118 so that the light beams being transmitted from the finger 102 to reach the image sensor 110.

The color controllable light sources 118 are controllable to emit light of different color. In one embodiment, the color controllable light sources are comprised in an organic light emitting diode (OLED) display 104.

A color filter layer 119 is arranged under the array of microlenses 117 and comprises alternating filter element types 116a and 116b of different colors for adjacent pixels or subsets of pixels in the photodetector pixel array of the image sensor 110.

The color filter elements may have a size being substantially the same as one pixel of the image sensor 110. In other words, one filter element may cover a single pixel of the image sensor 110. Further, a light source or pixel of the display, for example an OLED display, is typically smaller than a filter element. Thus, there herein denoted light source 107 may equally well denote a group of adjacent light sources that emit light of the same color. For example, a group 107 of light sources may comprise two or more pixels of the color controllable light source, such as four pixels or more of the color controllable light sources, that correspond to a single pixel of the image sensor 110.

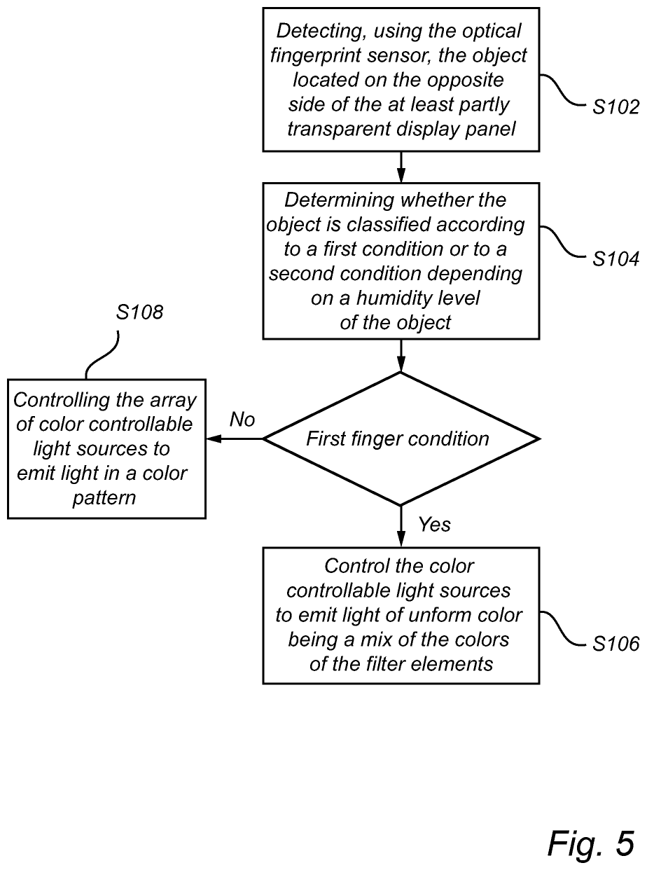

In conjunction with the flow-chart in FIG. 5, an object 102 located on the opposite side of the at least partly transparent display panel 104 is detected in step S102. The object 102 may be is classified according to a first finger condition or to a second finger condition depending on a humidity level of the object 102 in step S104.

As conceptually illustrated in FIG. 3C, if the finger 102 is classified according to a first finger condition, the color controllable light source 116 is controlled to emit light of uniform color being a mix of the colors of the filter elements in step S106. In the example illustrated in FIG. 3C each of the pixels 107 of the color controllable light source 118 emit light of the same color. Further, since the color of the light emitted from the color controllable light source 118 is a mix of the colors of the filter elements 116a-b, the light is transmissible though both filter types 116a-b to reach the image sensor 110. The waveband of the light emitted in response to the first condition overlaps at least partly with the spectral transmission band of both filter types. Preferably, the uniform light emitted is a mix of light having only wavelengths in the spectral transmission bands of the color filters.

In a preferred embodiment, the first finger condition is that the object, i.e., the finger 102 is determined to have a moisture level below a threshold indicative of a dry finger. In other words, in response to detecting that the finger 102 is dry, the color controllable light source is configured to emit light of uniform color that is transmissible though both filter types 116a-b. Since dry fingers tend to generate more diffuse or scattered reflections, it is generally more difficult to obtain high signal to noise at the image sensor, especially if a traditional pin hole arrangement is used. However, with the herein proposed embodiments, in response to the detected dry finger, the illuminated mixed uniform color provides for light that can be transmitted through both types of filter elements to thereby increase signal to noise and thereby also the image quality for dry fingers.

In response to another finger condition, such as a second finger condition, the color controllable light source 116 is controlled to emit a color pattern including the colors of the filter elements in step S108. In this case, groups of color controllable light sources are controlled to emit light corresponding to a color of the filter elements.

The color pattern can be provided in various ways in relation to the layout of the color filter layer 114.

For example, as conceptually illustrated in FIG. 3A, portions of the color controllable light sources, e.g., color controllable light sources 107a and 107b, are configured to emit light of the same color as the color of the filter type, 116a and 116b, arranged directly under the respective portion of the color controllable light sources. More specifically, the light source 107a being orthogonally directly above the filter element type 116a emits light of a color being transmissible through the color filter element type 116a. It can also be considered a light source is configured to emit light of a color corresponding to the color of the filter element that the light source is aligned with. Similarly, the light source 107b being orthogonally directly above the filter element 116b of a second type emits light of a color being transmissible through the second color filter element type 116b. This provides for primarily detecting normal incident light at the image sensor 110, which corresponds to specular reflections 112 from the finger 102.

A further example is shown in FIG. 3B, where, in response to the second finger condition, portions of the color controllable light sources, e.g., light sources 107a and 107b, are configured to emit light of the same color as the color of the filter type 116b and 116a adjacent to the filter type arranged directly under the respective portion of the color controllable light sources. In other words, the color of light emitted by a light source 107a is transmissible though a filter element type 116a that is not directly orthogonally under the light source 107a. It can also be considered a light source is configured to emit light of a color corresponding to the color of the filter element that the light source is not aligned with. The light of the light source 107a is of a color that is not transmissible through the filter element type 116b that is directly orthogonally under the light source 107a. This provides for primarily detecting more oblique incident light 111 at the image sensor 110.

Preferably, the second finger condition is that the object, i.e., the finger 102 is determined to have a moisture level above a threshold indicative of a finger having normal humidity.

Further, the light emitted in response to the first finger condition may be cyan light, and the color filter layer comprises alternating green 116a and blue 116b filter elements. As is known, cyan light is a mix of green and blue light. A further advantage of covering the pixels of the image sensor 110 with filter element types of green and blue is that it blocks red light and IR light which reduces the need for a separate IR-filter.

The color pattern emitted in response to the second finger condition may comprise distinguished green and blue areas.

The humidity level may be determined in various ways known as such in the art. For example, a capacitive measurement performed using the touch screen interface 106 of the electronic device 101 may determine whether the finger is dry or not. In other possible implementations, the humidity level may be determined form an image acquired by the optical fingerprint sensor and using suitable algorithms such as classifiers or neural networks.

Regardless, the optical fingerprint sensor 100 may either comprise, or being connected to, processing circuitry, e.g., control unit 202 for determining whether or not the object is classified to be of the first finger condition related to being a dry finger.

By means of the color pattern described above and the array of filter element types, it is possible to increase a pinhole size or reduce a thickness of a pinhole layer, or even avoid using a pinhole layer. In the embodiments conceptually shown in FIGS. 3A-C, the color filter layer 119 is attached to the image sensor 110 pixel array by an adhesive layer 130, e.g., an optical clear adhesive (OCA) layer 130. However, the color filter layer 119 may equally well be deposited directly on the pixel array of the image sensor 110. Further, the microlenses may also be manufactured directly on the image sensor 110, or they may be manufactured on a substrate that is attached to the image sensor 110.

By not using a pinhole layer, the optical fingerprint sensor is easier and cheaper to manufacture and stack-up of the optical fingerprint sensor 100 is reduced. Further, the margin for imaging dry fingers, i.e., of the of the first finger condition, is increased since more light can reach the pixels of the image sensor, in other words no light is blocked by a pinhole layer, and the scattered light from a dry finger can more easily reach the image sensor pixels. Further, the light is also not blocked by the filter layer 119 due to the advantageous combination of emitting color of uniform light being a mix of the colors of the filters.

However, for normal humid fingers, the contrast in acquired fingerprint images can be hampered by using too large or no pinholes. This is alleviated by applying the color pattern including the colors of the filter elements as suggested by the present invention. The color filter layer blocks either the oblique leakage from neighbouring microlenses as illustrated in FIG. 3A or blocks the normal light and only allows oblique leakage as illustrated in FIG. 3B. With the applied illumination with light in the color pattern, especially in the check board pattern, the proposed color filter layer effectively emulates a pinhole layer for improving the image contrast for normal humid fingers, whereas with the illumination of light with color of uniform light being a mix of the colors of the filters for dry fingers, the amount of light that reaches the image sensor is higher thereby improving signal to noise for dry fingers.

In some embodiments, now turning to FIG. 3D, the optical fingerprint sensor 100 comprises an opaque layer 121 arranged under the color filter layer 119 and covering an upper surface of the photodetector pixel array of the image sensor 110. The opaque layer 121 comprises a plurality of separate openings 120 arranged at a distance from each other. This opaque layer 121 with openings may form a pinhole layer. The pin hole layer 121 is preferable relatively thin.

The thickness of the pinhole layer is preferably in the range of 5-30 μm, preferably less than 25 μm and may be comprised a of a polymer substrate with an opaque material deposited thereon to form openings through which light can be transmitted towards the image sensor 110.

The size or width of the pinhole or opening 120 in a direction parallel to the pixel array of the image sensor 110 is preferably in the range of 2 μm to 6 μm. The width of a microlens 117 is larger than the width of the pinhole. In other words, each microlens 117 is arranged to cover a respective opening 120 of the optional opaque layer 121. The size of the pinhole 120 is smaller than the size of a pixel of the image sensor 110. One microlens may cover a single pixel in the image sensor pixel array.

The microlenses may be arranged or manufactured or a transparent substrate 125 on which the filter elements may be attached. The pinhole layer 121 is attached to the filter layer 119 so that the filter layer 119 is sandwiched between the transparent substrate 125 and the opaque layer 121. The thickness of the transparent substrate 125 may be in the range of 5 μm to 15 μm.

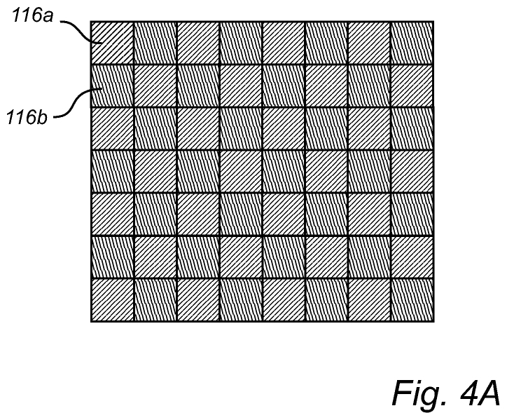

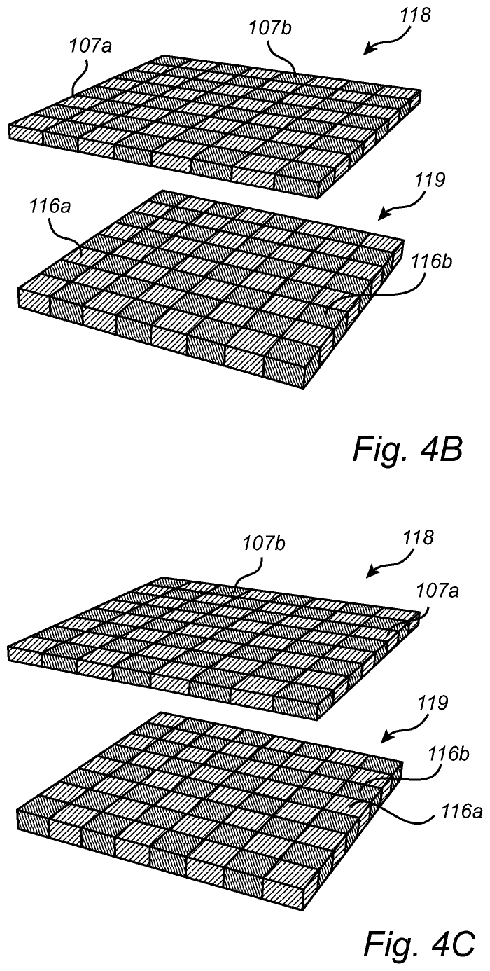

FIG. 4A conceptually illustrates a color filter 114 as seen from the image sensor or form the object 102 side. The alternating filter element types 116a and 116b of the color filter layer 114 are arranged in a chess board pattern.

In FIG. 4B, a color controllable light sources 118 is shown emitting a color pattern in response to the second finger condition. The color pattern comprises portions of light corresponding to color controllable light source 107a adapted to be transmissible through one of the filter types 116a and not through the other filter type 116b. The color pattern is a chess board pattern of alternating colors of light. The color pattern here emitted so that the color filter type directly under the respective color portion in the color controllable light source 118 is the same, as also shown in FIG. 3A.

FIG. 4C illustrates another conceptual example where the color pattern is a chess board pattern of alternating colors of light. However, in this example, the color pattern is emitted so that the color filter type directly under the respective color portion in the color controllable light source 118 is not the same, as also shown in FIG. 3B. For example, light source 107a is directly above filter type 116b which is adjacent to filter type 116a being of the same color as light source 107a.

The light sources herein indicated as 107a, 107b and 107 may comprise one or several individual light emitting units, but that collectively emit light of the color indicated for the respective light source.

The optical fingerprint sensor 100 further comprises an adhesive layer used to attach the display panel 104 and the optical fingerprint sensor 100. However, there may be an air gap between the transparent display panel 104 and the microlenses 117.

Furthermore, the optical fingerprint sensor 100 may also comprise an antireflection coating, infrared filters, and/or a polarizing filter, which are not illustrated separately herein.

The control unit 202 may be arranged to perform the method described in relation to FIG. 5.

A control unit may include a microprocessor, microcontroller, programmable digital signal processor or another programmable device. The control unit may also, or instead, include an application specific integrated circuit, a programmable gate array or programmable array logic, a programmable logic device, or a digital signal processor. Where the control unit includes a programmable device such as the microprocessor, microcontroller or programmable digital signal processor mentioned above, the processor may further include computer executable code that controls operation of the programmable device. It should be understood that all or some parts of the functionality provided by means of the control unit (or generally discussed as “processing circuitry”) may be at least partly integrated with the optical fingerprint sensor.

Even though the invention has been described with reference to specific exemplifying embodiments thereof, many different alterations, modifications and the like will become apparent for those skilled in the art. Also, it should be noted that parts of the imaging device and method for manufacturing the imaging device may be omitted, interchanged or arranged in various ways, the imaging device yet being able to perform the functionality of the present invention.

Sizes and dimensions of various components and elements shown in the drawings are not necessarily to scale and are generally selected for clarity in the drawings. For example, the thickness of filters, displays, opaque layers, etc., may not correspond to a real implementation.

The microlenses are herein illustrated as plano-convex lenses having the flat surface orientated towards the transparent substrate. It is also possible to use other lens configurations and shapes. A plano-convex lens may for example be arranged with the flat surface towards the display panel, and in one embodiment the lens may be attached to a bottom surface of the display panel even though the imaging performance may be degraded compared to the reverse orientation of the microlens. It is also possible to use other types of lenses such as convex lenses. An advantage of using a plano-convex lens is the ease of manufacturing and assembly provided by a lens having a flat surface.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

1. An optical fingerprint sensor configured to be arranged under an at least partially transparent display panel and configured to capture an image of an object located on an opposite side of the at least partly transparent display panel which comprises an array of color controllable light sources configured for illuminating the object for capturing an image, the optical fingerprint sensor comprising:
an image sensor comprising a photodetector pixel array;
an array of microlenses arranged under the color controllable light sources to redirect light towards the photodetector pixel array;
a color filter layer arranged under the array of microlenses to at least partly cover the photodetector pixel array, the color filter layer comprising alternating filter element types of different colors for adjacent subsets of pixels in the photodetector pixel array, a spectral transmission band of each color filter band corresponding to the respective color;
wherein the color controllable light sources are controllable,
in response to a first finger condition related to a humidity level of the object, to emit light of uniform color including a mix of the colors of the filter elements, and
in response to a second finger condition related to a humidity level of the object, to emit a color pattern including the colors of the filter elements, wherein groups of color controllable light sources are controlled to emit light corresponding to a color of the filter elements.

2. The optical fingerprint sensor according to claim 1, wherein, when emitting light in response to the second finger condition, the color pattern comprises portions of light adapted to be transmissible through one of the filter types and not through the other filter type.

3. The optical fingerprint sensor according to claim 1, wherein the color pattern is a chess board pattern of alternating colors of light.

4. The optical fingerprint sensor according to claim 1, wherein the alternating filter element types of the color filter layer are arranged in a chess board pattern.

5. The optical fingerprint sensor according to claim 1, wherein in response to the second finger condition, portions of the color controllable light sources are configured to emit light of the same color as the color of the filter type arranged under the respective portion of the color controllable light sources.

6. The optical fingerprint sensor according to claim 1, wherein in response to the second finger condition, portions of the color controllable light sources are configured to emit light of the same color as the color of the filter type adjacent to the filter type arranged under the respective portion of the color controllable light sources.

7. The optical fingerprint sensor according to claim 1, wherein the first finger condition is that the object is determined to have a moisture level below a threshold indicative of a dry finger.

8. The optical fingerprint sensor according to claim 1, wherein the second finger condition is that the object is determined to have a moisture level above a threshold indicative of a finger having normal humidity.

9. The optical fingerprint sensor according to claim 1, comprising, or being connected to, processing circuitry for determining whether or not the object is classified to be of the first finger condition related to being a dry finger.

10. The optical fingerprint sensor according to claim 1, wherein the color controllable light sources are comprised in an organic light emitting diode display.

11. The optical fingerprint sensor according to claim 1, wherein the light emitted in response to the first finger condition is cyan light, and the color filter layer comprises alternating green and blue filter elements.

12. The optical fingerprint sensor according to claim 1, wherein the color pattern emitted in response to the second finger condition comprises distinguished green and blue areas.

13. The optical fingerprint sensor according to claim 1 comprising an opaque layer arranged under the color filter layer and covering an upper surface of the photodetector pixel array, wherein the opaque layer further comprises a plurality of separate openings.

14. An electronic device comprising:
an at least partly transparent display panel,
the optical fingerprint sensor according to claim 1, and processing circuitry configured to:
receive a signal from the optical fingerprint sensor indicative of a fingerprint of a finger touching the at least partly transparent display panel,
perform a fingerprint authentication procedure based on information comprised in the signal.

15. The electronic device according to claim 14, wherein the electronic device is a mobile device.

16. A method for detecting a fingerprint using an optical fingerprint sensor arranged under an at least partially transparent display panel and configured to capture an image of an object located on an opposite side of the at least partly transparent display panel which comprises an array of color controllable light sources, the optical fingerprint sensor comprises:
an image sensor comprising a photodetector pixel array;
an array of microlenses arranged under the color controllable light sources to redirect light towards the photodetector pixel array;
a color filter layer arranged under the array of microlenses to at least partly cover the photodetector pixel array, the color filter layer comprising alternating filter element types of different colors for adjacent subsets of pixels in the photodetector pixel array, a spectral transmission band of each color filter band corresponding to the respective color;
wherein the method comprises:
detecting, using the optical fingerprint sensor, an object located on the opposite side of the at least partly transparent display panel;
determining whether the object is classified according to a first finger condition or to a second finger condition depending on a humidity level of the object; wherein
in response to a determining that the object is classified according to the first finger condition, controlling the color controllable light sources to emit light of uniform color being a mix of the colors of the filter elements,
otherwise, controlling groups of color controllable light sources to emit light corresponding to a respective color of the filter elements so that a color pattern including the colors of the filter elements is emitted.

17. The method according to claim 16, comprising:
in response to a determining that the object is classified according to the first finger condition, controlling the array of color controllable light sources to emit cyan light,
otherwise, controlling the array of color controllable light sources to emit light in a color pattern comprising blue and green light.

18. A control unit configured to perform the steps of claim 16.
